(19) United States
(12) Patent Application Publication
(10) Pub. No.: US 2025/0113446 A1
(43) Pub. Date: Apr. 3, 2025

(54) PLATED THROUGH-HOLE STRUCTURES AND METHOD FOR THE MANUFACTURE THEREOF

(71) Applicant: ROGERS CORPORATION, Chandler, AZ (US)

(72) Inventors: Michael S. Kuszaj, Brooklyn, CT (US); Allen F. Horn, III, Pomfret Center, CT (US)

(21) Appl. No.: 18/901,575

(22) Filed: Sep. 30, 2024

Related U.S. Application Data
(60) Provisional application No. 63/542,121, filed on Oct. 3, 2023.

(51) Int. Cl. H05K 3/42; H05K 3/00

(52) U.S. Cl. CPC H05K 3/42; H05K 3/0044

(57) ABSTRACT

A method for forming a plated through-hole structure includes filling a first through-hole in a substrate with a composition having a coefficient of thermal expansion of less than 50 ppm/° C. The composition is disposed on the interior surface of the first through-hole from the first opening to the second opening. The method further includes forming a second through-hole in the first through-hole filled with the composition. The second through-hole has a diameter less than a diameter of the first through-hole. The method further includes plating the interior surface of the second through-hole to provide the plated through-hole structure. The method can provide plated through-hole structures exhibiting good adhesion to metal and providing a reliable electrical connection.

### CROSS-REFERENCE TO RELATED APPLICATION

This application claims priority to U.S. Provisional Patent Application No. 63/542,121, filed on Oct. 3, 2023, the contents of which are hereby incorporated by reference in their entirety.

### BACKGROUND

Conductive metal plates are often used as heat dissipating materials in electrical circuitry. To create electrical connections, plated through-holes (PTHs) can be made by drilling a hole through the metal plate and subsequently filling the hole with a dielectric material. The dielectric material should adhere sufficiently to the metal plate to allow for drilling through the dielectric material for placement of a conductor material. The dielectric material should also allow for plating of the conductor material without causing short circuiting to the metal plate.

Accordingly, there remains a need in the art for improved plated through-hole structures that can overcome the above-described technical limitations of existing materials. It would be particularly advantageous to provide a plated through-hole structure wherein the dielectric material exhibits good adhesion to metal and can provide a reliable electrical connection.

### SUMMARY

An aspect of the present disclosure is a method for forming a plated through-hole structure, the method comprising: filling a first through-hole in a substrate with a composition having a coefficient of thermal expansion of less than 50 ppm/° C., wherein the first through-hole has a first opening at a first side of the substrate, a second opening at a second, opposite side of the substrate, and an interior surface defining the first through-hole and extending from the first opening to the second opening, wherein the composition is disposed on the interior surface of the first through-hole from the first opening to the second opening; forming a second through-hole in the first through-hole comprising the composition, wherein the second through-hole has a diameter less than a diameter of the first through-hole, an opening at the first side of the substrate, an opening at the second, opposite side of the substrate, and an interior surface defining the second through-hole and extending from the opening at the first side of the substrate to the opening at the second side of the substrate; and plating the interior surface of the second through-hole to provide the plated through-hole structure.

Another aspect is a plated through-hole structure made by the method.

Another aspect is a plated through-hole structure comprising: a substrate comprising a first through-hole having a first opening at a first side of the substrate, a second opening at a second, opposite side of the substrate, and an interior surface defining the first through-hole and extending from the first opening to the second opening; wherein the first through-hole has a composition having a coefficient of thermal expansion of less than 50 ppm/° C. disposed on the interior surface of the first through-hole from the first opening to the second opening; and a plated metal layer on the composition.

Another aspect is a multilayer circuit board comprising the plated through-hole structure.

The above described and other features are exemplified by the following figures and detailed description.

### BRIEF DESCRIPTION OF THE DRAWINGS

The following figures represent exemplary embodiments.

FIG. 1 is an image showing a cross section of plated through-hole structure according to Comparative Example 5.

FIG. 2 is an image showing a cross section of plated through-hole structure according to Comparative Example 7.

FIG. 3 is an image showing a cross section of plated through-hole structure according to Example 1.

FIG. 4 is an image showing a cross section of plated through-hole structure according to Example 2.

### DETAILED DESCRIPTION

The present inventor has discovered that a particular dielectric material can provide plated through-holes in a substrate (also referred to herein as “plated through-hole structures) which can overcome the above-described technical limitations. In particular, the present inventor has advantageously discovered that selecting a composition comprising a dielectric material having a particular coefficient of thermal expansion (CTE) as it relates to the metal layer can provide the desired combination of properties. A significant improvement is therefore provided by the present disclosure.

Accordingly, an aspect of the present disclosure is a method for forming a plated through-hole structure. The method comprises filling a first through-hole in a substrate (also referred to herein as a substrate through-hole” or “first through-hole”) with a composition having a coefficient of thermal expansion of less than 50 ppm/° C. The substrate comprises at least one through-hole, and preferably comprises a plurality of through-holes. Each substrate through-hole has a first opening at a first side of the substrate and a second opening at a second, opposite side of the substrate. Each substrate through-hole further has an interior surface defining the substrate through-hole and extending from the first opening to the second opening (i.e., traversing the entire thickness of the substrate). The interior surface of the substrate through-hole comprises a material of the substrate. Each substrate through-hole present in the substrate can be formed, for example, by drilling the substrate through-hole in the substrate.

The substrate can generally be any suitable substrate including one or more through-holes. In an aspect, the substrate is a conductive substrate. The substrate can comprise, for example, a metal or a metal alloy. In an aspect, the substrate can comprise a conductive metal substrate, for example comprising copper, aluminum, brass, and the like, or an alloy thereof. In an aspect the substrate can be a layered material, for example comprising copper-invar-copper, copper-molybdenum-copper, and the like. In a specific aspect, the substrate is a copper or aluminum substrate.

The substrate through-hole is filled with a composition having a coefficient of thermal expansion of less than 50 ppm/° C. (also referred to herein as “the composition”). The composition is disposed on the interior surface of the substrate through-hole from the first opening to the second opening. The composition preferably completely fills the substrate through-hole.

In an aspect, the composition can comprise a thermoplastic polymer or thermosetting polymer matrix.

As used herein, the term “thermoplastic” refers to a material that is plastic or deformable, melts to a liquid when heated, and freezes to a brittle, glassy state when cooled sufficiently. Thermoplastics are typically high molecular weight polymers. Examples of thermoplastic polymers that can be used include polyacetals (e.g., polyoxyethylene and polyoxymethylene), poly(C₁₋₆ alkyl) acrylates, polyacrylamides, polyamides, (e.g., aliphatic polyamides, polyphthalamides, and polyaramides), polyamideimides, polyanhydrides, polyarylates, polyarylene ethers (e.g., polyphenylene ethers), polyarylene sulfides (e.g., polyphenylene sulfides), polyarylsulfones, polybenzothiazoles, polybenzoxazoles, polycarbonates (including polycarbonate copolymers such as polycarbonate-siloxanes, polycarbonate-esters, and polycarbonate-ester-siloxanes), polyesters (e.g., polyethylene terephthalates, polybutylene terephthalates, polyarylates, and polyester copolymers such as polyester-ethers), polyetheretherketones, polyetherimides (including copolymers such as polyetherimide-siloxane copolymers), polyetherketoneketones, polyetherketones, polyethersulfones, polyimides (including copolymers such as polyimide-siloxane copolymers), poly(C₁₋₆ alkyl) methacrylates, polymethacrylamides, polynorbornenes (including copolymers containing norbornenyl units) polyolefins (e.g., polyethylenes, polypropylenes, polytetrafluoroethylenes, and their copolymers, for example ethylene-alpha-olefin copolymers), polyoxadiazoles, polyoxymethylene, polyphthalides, polysilazanes, polysiloxanes, polystyrenes (including copolymers such as acrylonitrile-butadiene-styrene (ABS) and methyl methacrylate-butadiene-styrene (MBS)), polysulfides, polysulfonamides, polysulfonates, polysulfones, polythioesters, polytriazines, polyureas, polyurethanes, polyvinyl alcohols, polyvinyl esters, polyvinyl ethers, polyvinyl halides, polyvinyl ketones, polyvinyl thioethers, polyvinylidene fluorides, or the like, or a combination comprising at least one of the foregoing thermoplastic polymers.

In an aspect, the composition can comprise a fluoropolymer, for example a fluorinated polyolefin. “Fluoropolymers” as used herein, include homopolymers and copolymers that comprise repeat units derived from a fluorinated alpha-olefin monomer, i.e., an alpha-olefin monomer that includes at least one fluorine atom substituent, and optionally, a non-fluorinated, ethylenically unsaturated monomer reactive with the fluorinated alpha-olefin monomer. Exemplary fluorinated alpha-olefin monomers include CF₂═CF₂, CHF═CF₂, CH₂═CF₂, CHCl═CHF, CClF═CF₂, CCl₂═CF₂, CClF═CClF, CHF═CCl₂, CH₂═CClF, CCl₂—CClF, CF₃CF═CF₂, CF₃CF═CHF, CF₃CH═CF₂, CF₃CH═CH₂, CHF₂CH═CHF, CF₃CF═CF₂, and perfluoro (C₂₋₈ alkyl) vinylethers such as perfluoromethyl vinyl ether, perfluoropropyl vinyl ether, and perfluorooctylvinyl ether. The fluorinated alpha-olefin monomer can comprise tetrafluoroethylene (CF₂═CF₂), chlorotrifluoroethylene (CClF═CF₂), (perfluorobutyl)ethylene, vinylidene fluoride (CH₂═CF₂), hexafluoropropylene (CF₂═CFCF₃), or a combination comprising at least one of the foregoing. Exemplary non-fluorinated monoethylenically unsaturated monomers include ethylene, propylene, butene, and ethylenically unsaturated aromatic monomers such as styrene and alpha-methyl-styrene. Exemplary fluoropolymers include poly(chlorotrifluoroethylene) (PCTFE), poly(chlorotrifluoroethylene-propylene), poly(ethylene-tetrafluoroethylene) (ETFE), poly(ethylene-chlorotrifluoroethylene) (ECTFE), poly(hexafluoropropylene), poly(tetrafluoroethylene) (PTFE), poly(tetrafluoroethylene-ethylene-propylene), poly(tetrafluoroethylene-hexafluoropropylene) (also known as fluorinated ethylene-propylene copolymer (FEP)), poly(tetrafluoroethylene-propylene) (also known as fluoroelastomer (FEPM), poly(tetrafluoroethylene-perfluoropropylene vinyl ether), a copolymer having a tetrafluoroethylene backbone with a fully fluorinated alkoxy side chain (also known as a perfluoroalkoxy polymer (PFA)) (for example, poly(tetrafluoroethylene-perfluoroproplyene vinyl ether)), polyvinylfluoride (PVF), polyvinylidene fluoride (PVDF), poly(vinylidene fluoride-chlorotrifluoroethylene), perfluoropolyether, perfluorosulfonic acid, and perfluoropolyoxetane, or a combination comprising at least one of the foregoing. The fluoropolymer can comprise at least one of a perfluoroalkoxy alkane polymer or a fluorinated ethylene-propylene. The fluoropolymer can comprise a perfluoroalkoxy alkane polymer. A combination comprising at least one of the foregoing fluoropolymers can be used.

In an aspect, the fluoropolymer can comprise at least one of FEP, PFA, ETFE, or PTFE, which can be fibril forming or non-fibril forming. FEP is available, for example, under the trade name TEFLON FEP from DuPont or NEOFLON FEP from Daikin; and PFA is available, for example, under the trade name NEOFLON PFA from Daikin, TEFLON PFA from DuPont, or HYFLON PFA from Solvay Solexis.

In an aspect, the fluoropolymer can comprise PTFE. The PTFE can comprise a PTFE homopolymer, a trace modified PTFE homopolymer, or a combination comprising one or both of the foregoing. As used herein, a trace modified PTFE homopolymer comprises less than 1 weight percent (wt %) of a repeat unit derived from a co-monomer other than tetrafluoroethylene based on the total weight of the homopolymer.

In an aspect, the composition can comprise a thermosetting polymer matrix. Thermoset polymers are derived from thermosetting monomers or prepolymers (resins) that can irreversibly harden and become insoluble with polymerization or cure, which can be induced by heat or exposure to radiation (e.g., ultraviolet light, visible light, infrared light, or electron beam (e-beam) radiation). Thermoset polymers include alkyds, bismaleimide polymers, bismaleimide triazine polymers, cyanate ester polymers, benzocyclobutene polymers, benzoxazine polymers, diallyl phthalate polymers, epoxies, hydroxymethylfuran polymers, melamine-formaldehyde polymers, phenolics (including phenol-formaldehyde polymers such as novolacs and resoles), benzoxazines, polydienes such as polybutadienes (including homopolymers or copolymers thereof, e.g., poly(butadiene-isoprene)), polyisocyanates, polyureas, polyurethanes, triallyl cyanurate polymers, triallyl isocyanurate polymers, certain silicones, and polymerizable prepolymers (e.g., prepolymers having ethylenic unsaturation, such as unsaturated polyesters, polyimides), or the like. The prepolymers can be polymerized, copolymerized, or crosslinked, e.g., with a reactive monomer such as styrene, alpha-methylstyrene, vinyltoluene, chlorostyrene, acrylic acid, (meth)acrylic acid, a (C₁₋₆ alkyl) acrylate, a (C₁₋₆ alkyl) methacrylate, acrylonitrile, vinyl acetate, allyl acetate, triallyl cyanurate, triallyl isocyanurate, or acrylamide.

In an aspect the composition is selected such that the coefficient of thermal expansion of the composition is no more than three times greater than the coefficient of thermal expansion of the substrate.

The composition can further comprise a filler (e.g., the composition can be a composite material comprising a polymer matrix and a filler, e.g., a ceramic filler). In an aspect, the filler can have a low coefficient of thermal expansion. Such fillers can include, for example, glass beads, silica, or ground micro-glass fibers. In an aspect, the filler comprises silica, titania, barium nanotitanate, or a combination thereof. In a specific aspect, the filler comprises silica.

The fillers can be in the form of solid, porous, or hollow particles. The particle size of the filler particles can affect a number of important properties including coefficient of thermal expansion, modulus, elongation, and flame resistance. In an aspect, the filler particles can have an average particle size of 0.1 to 15 micrometers, specifically 0.2 to 10 micrometers.

The filler can be present in an amount of 50 to 65 volume percent, based on the total volume of the composite material.

Prior to filling the substrate through-hole, the composition can be in the form of a cylindrical rod. For example, the composition can be in the form of a cylindrical rod having a diameter that is within 10% of a diameter of the substrate through-hole, preferably within 5% of the diameter of the substrate through-hole. In another example, the composition can be in the form of a cylindrical rod having a diameter that is up to 10% greater than a diameter of the substrate through-hole, preferably up to 5% greater than the diameter of the substrate through-hole. In an aspect, the cylindrical rod can have a diameter that ranges from the hole diameter minus 0.002 inches to the hole diameter plus 0.005 inches.

In an aspect, the cylindrical rod can have a length that is greater than a thickness of the substrate. For example, the length of the cylindrical rod can have a length that is equal to the thickness of the substrate plus up to 20%, or up to 10%, of the diameter of the hole being filled.

Filling the substrate through-hole can comprise inserting the composition in the form of the cylindrical rod into the substrate through-hole. The inserting can be repeated for each substrate through-hole present in the substrate. The method can optionally further comprise applying pressure to the composition in the substrate through-hole to provide a head (e.g., a volume of composition having a diameter greater than a diameter of the substrate through-hole) comprising the composition at one or both of the first opening and the second opening. The head can form with the dielectric material disposed thereon in a subsequent step to provide a uniform layer. In an aspect, the pressure applied to the composition to form the head is greater than a pressure that may be used to insert the rod into the substrate through-hole. In an aspect, the inserting and forming the nail head can be conducted in a single step. The applied pressure is sufficient to form the head such that the rod is prevented from being inadvertently removed from the substrate.

Advantageously, using the method described herein, no voids are present between the interior surface of the substrate through-hole and the composition.

In an aspect, the method can optionally further comprise laminating a dielectric material on each side of the substrate after filling the substrate through-hole with the composition. Exemplary dielectric materials can include a thermoplastic material optionally comprising a filler. In a specific aspect, a dielectric material can comprise a fluoropolymer (e.g., PTFE), optionally comprising a dielectric filler (e.g., silica). The dielectric material can be the same or different from the composition used to fill the substrate through-hole. In an aspect, the dielectric material and the composition filling the substrate through-hole are the same, preferably each comprising a fluoropolymer. In an aspect, the dielectric material and the composition filling the substrate through-hole are the same, preferably each comprising a fluoropolymer and a filler, preferably a silica filler.

After filling the substrate through-hole with the composition, the method further comprises forming a second through-hole in the filled substrate through-hole (i.e., forming a second through-hole in the composition present in the first through-hole). The second through-hole has a diameter that is less than the diameter of the first through-hole. The second through-hole has an opening at the first side of the substrate, an opening at the second, opposite side of the substrate, and an interior surface defining the second through-hole and extending from the opening at the first side of the substrate to the opening at the second side of the substrate. The interior surface of the second through-hole comprises the composition that was used to fill the substrate through-hole.

The method further comprises plating the second through-hole to provide the desired plated through-hole structure. The plating can provide a thin layer of a conductive material disposed on the interior surface of the second through-hole. Preferably, the conductive material is copper. The plating can be by, for example, electroless plating (e.g., electroless copper plating), followed by electrolytic plating (e.g., electrolytic copper plating). Plating processing conditions are generally known and can be determined by the skilled person without undue experimentation guided by the present disclosure.

The method can optionally further comprise laminating a conductive layer on the plated through-hole structure. Stated another way, a conductive layer can be laminated on the first side of the substrate having the plated through-holes, the second side of the substrate having the plated through-holes, or both the first and second sides of the substrate having the plated through-holes. The conductive layer preferably comprises the same conductive material disposed on the interior surface of the second through-hole. In an aspect, the conductive layer comprises copper.

Another aspect of the present disclosure is a plated through-hole structure (i.e., a substrate having plated through-holes for example made according to the method disclosed herein). The plated through-hole structure comprises a substrate having a substrate through-hole. The substrate through-hole is filled with a composition having a coefficient of thermal expansion of less than 50 ppm/° C. disposed on, e.g., directly on, the interior surface of the substrate through-hole from the first opening to the second opening. The composition filling the substrate through-hole has a second through-hole disposed therein, the second through-hole having a metal layer on the interior surface of the second through-hole (i.e., disposed on, e.g., directly on, the interior surface of the second through-hole from the first opening to the second opening, the interior surface of the second through-hole comprising the composition). The substrate is preferably a conductive substrate, for example comprising copper or aluminum. Advantageously, no voids are present between the interior surface of the substrate through-hole and the composition, thus providing a significant technical advantage over previous plated through-hole structures.

The plated through-hole structures made by the method described herein can be particularly useful in circuit board applications. Accordingly, a multilayer circuit board comprising the plated through-hole structure describe herein represents another aspect of the present disclosure. For example, a multilayer circuit board can comprise the plated through-hole structure located between a first conductive layer and a second conductive layer. Useful conductive layers include, for example, at least one of stainless steel, copper, gold, silver, aluminum, zinc, tin, lead, or a transition metal. There are no particular limitations regarding the thickness of the conductive layer, nor are there any limitations as to the shape, size, or texture of the surface of the conductive layer. The conductive layer can have a thickness of 3 to 200 micrometers, or 9 to 180 micrometers. When two or more conductive layers are present, the thickness of the two layers can be the same or different. The conductive layer can comprise a copper layer. Suitable conductive layers include a thin layer of a conductive metal such as a copper foil presently used in the formation of circuits, for example, electrodeposited copper foils. The copper foil can have a root mean squared (RMS) roughness of less than or equal to 2 micrometers, or less than or equal to 0.7 micrometers, where roughness is measured using a Veeco Instruments WYCO Optical Profiler, using the method of white light interferometry.

The conductive layer can be applied by laminating the conductive layer onto the plated through-hole structure or by adhering the conductive layer to the plated through-hole structure via an adhesive layer. Other methods known in the art can be used to apply the conductive layer where permitted by the particular materials and form of the circuit material, for example, electrodeposition, chemical vapor deposition, and the like.

The laminating can entail laminating a multilayer stack comprising the plated through-hole structure, a conductive layer, and an optional intermediate layer between the plated through-hole structure and the conductive layer to form a layered structure. The conductive layer can be in direct contact with the plated through-hole structure, without the intermediate layer. The layered structure can then be placed in a press, e.g., a vacuum press, under a pressure and temperature and for duration of time suitable to bond the layers and form a laminate. Lamination and optional curing can be by a one-step process, for example, using a vacuum press, or can be by a multi-step process. In a one-step process, the layered structure can be placed in a press, brought up to laminating pressure (e.g., 150 to 2,500 pounds per square inch (psi) (1 to 17 megapascals)) and heated to laminating temperature (e.g., 150 to 390° C.). The laminating temperature and pressure can be maintained for a desired time, e.g., up to 20 minutes, and thereafter cooled (while still under pressure), for example to a temperature of less than or equal to 150° C.

If present, the intermediate layer can comprise a polyfluorocarbon film that can be located in between the conductive layer and the plated through-hole structure, and an optional layer of microglass reinforced fluorocarbon polymer can be located in between the polyfluorocarbon film and the conductive layer. The layer of microglass reinforced fluorocarbon polymer can increase the adhesion of the conductive layer to the plated through-hole structure. The microglass can be present in an amount of 4 to 30 wt % based on the total weight of the layer. The microglass can have a longest length scale of less than or equal to 900 micrometers, or less than or equal to 500 micrometers. The microglass can be microglass of the type as commercially available by Johns-Manville Corporation of Denver, CO. The polyfluorocarbon film comprises a fluoropolymer (such as polytetrafluoroethylene (PTFE), a fluorinated ethylene-propylene copolymer (such as Teflon FEP), and a copolymer having a tetrafluoroethylene backbone with a fully fluorinated alkoxy side chain (such as Teflon PFA)).

The various layers can fully or partially cover each other, and additional copper foil layers, patterned circuit layers, and substrate layers can also be present. It is understood that the various layers can be in direct physical contact with neighboring layers (directly on) or layers such as adhesive layers can be located there between (on).

The following examples are provided to illustrate the present disclosure. The examples are merely illustrative and are not intended to limit devices made in accordance with the disclosure to the materials, conditions, or process parameters set forth therein.

### EXAMPLES

### Comparative Example 1

Approximately 250 through-holes, each having a diameter of 0.040 inches (in) (1.016 millimeters (mm)) were drilled into a copper plate having a thickness of 0.110 inches (2.794 mm). Layers of a thermosetting poly(phenylene ether) (PPE) circuit prepreg material were laminated onto the metal plate using a flat-bed, resulting in the through-holes being filled with the PPE dielectric material. Ten plies (five plies per side) of the thermosetting circuit prepreg were used in the laminating step. After fully curing, the prepreg layers were removed from the metal plate surfaces by sanding. Holes (diameter of 0.012 inches (0.305 mm)) were drilled through the center of the dielectric-filled holes and plated using an electroless copper deposition process followed by galvanic plating to yield approximately 0.001″ thick copper inside the plated through-holes (PTHs). Examination of a cross-section through the center line of the through-holes under a microscope indicated that the prepreg resin had separated from the through-hole walls, and that the plating resulted in shorting of the conductor to the ground plane.

The thermosetting PPE circuit prepreg material has a z-axis CTE of 55 ppm/° C. from 50° C. to Tg of 260° C. In contrast, the copper plate has a CTE of 17 ppm/° C. The delamination of the resin from the metal is attributed, at least in part, to the difference in CTE (e.g., a CTE of 55 ppm/° C. for the PPE compared to a CTE of 17 ppm/° C. for the copper plate).

### Comparative Example 2

A semi-rigid coaxial cable was used to fill through-holes in a substrate, providing connections between signal layers on opposite sides of the copper plate. The semi-rigid coaxial cable comprises a solid copper center conductor, a pure polytetrafluoroethylene (PTFE) insulation layer, and an outer conductor made of copper tubing. The semi-rigid cable had an outer conductor diameter of 0.047 inches (1.19 millimeters (mm)), and included the inner conductor and insulation at sizes capable of achieving a 50 ohm impedance.

Through-holes slightly larger than the 0.047 in (1.19 mm) outer conductor diameter of the semi-rigid cable were drilled through the copper plate having a thickness of 0.110 inches (2.794 mm). The cable was cut to slightly longer than 0.110 inches (2.794 mm) thick and inserted in the copper plate. The surface of the copper plate including the inserted cables was planarized by sanding and plated with electrolytic copper to bond the outer conductors of the inserted cables to the plated surface.

Single plies of a thermosetting, glass reinforced poly(phenylene ether) (PPE) prepreg as a dielectric layer and copper foils were bonded to both sides of the copper plate including the cables. When the through-holes were examined by cross sectioning, it was seen that voids were present where the dielectric layers and the PTFE dielectric of the cable had been in contact, which is believed to be due to the high CTE value of unreinforced PTFE relative to copper. Unreinforced PTFE exhibits a CTE of about 200 ppm/° C., which was sufficient to leave voids in the dielectric layer.

### Comparative Example 3

The process of Comparative Example 2 was repeated, except that the substrate including the inserted cables was baked to relieve stress in the PTFE dielectric layer before sanding. After lamination of the copper and dielectric layers, the part was cross sectioned and delamination was again observed.

### Comparative Example 4

The process of Comparative Example 2 was repeated, except that a small amount (e.g., a few mils) of the PTFE was removed at the cable ends by ablation with a CO₂ laser. The surface of the PTFE was plasma treated to promote adhesion to the PPE prepreg before lamination. Cross-sectioning and evaluation by microscope revealed that the PTFE dielectric had pulled away from the semi-rigid coaxial cable outer conductor. The delamination was again attributed to the difference in CTE of the materials (i.e., the PTFE and the outer copper conductor of the coaxial cable).

### Comparative Example 5

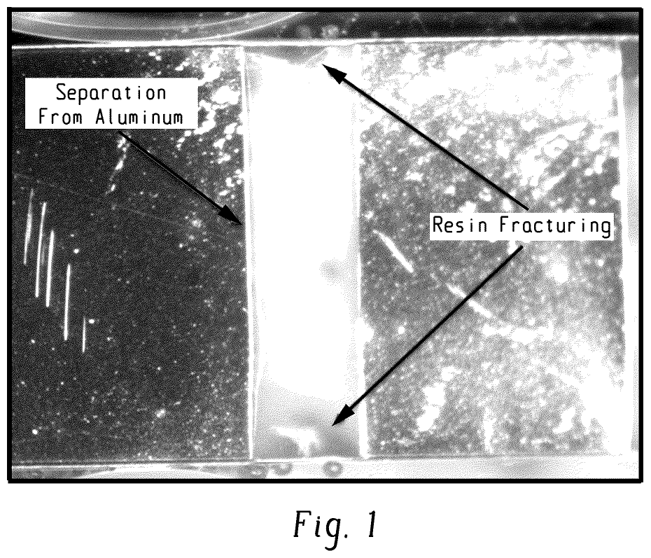

Sixty through-holes having a diameter of 0.065 inches (1.651 mm) were drilled into an aluminum plate having a thickness of 0.2 inches (5.08 mm). Thermosetting material obtained as 2929 Bondply from Rogers Corporation (0.0045 inches (0.1143 mm) thick) and copper foils were laminated on both side of the plate. Cross-sectioning and analysis shows that while the through-holes had filled in as a result of the lamination, the 2929 Bondply material had separated from the through-hole walls (FIG. 1). The 2929 Bondply has a CTE of 50 ppm/° C., while the aluminum plate has a CTE of 22 ppm/° C.

### Comparative Example 6

Sixty through-holes, each having a diameter of 0.065 inches (1.651 mm) were drilled into an aluminum plate having a thickness 0.2 inches (5.08 mm). PTFE was blended with a lubricant (e.g., dipropylene glycol). The blend was extruded through a conical spaghetti die to form a rod. The resulting rod was washed, dried, and sintered at 371° C. to increase the density. The length of the rod was selected to be 0.005 inches (0.127 mm) longer than the thickness of the aluminum plate. The rod diameter was 0.065″ (1.651 mm) after sintering. The extruded and cut PTFE rods were inserted into the through-holes drilled into the aluminum plate. The rods were compressed with a roller, resulting in “nail heads” on both sides of the plate. A silica filled PTFE dielectric layer obtained as Xtreme RO1200 Bondply from Rogers Corporation having a thickness of 0.003 inches (0.0762 mm) and a sheet of copper foil were laminated onto each side of the aluminum plate at a temperature of 371° C. and 1,000 pounds per square inch (psi) (6.89 megapascals (MPa)). Cross-sectioning and analysis revealed the PTFE rods were separated from the aluminum plate.

### Comparative Example 7

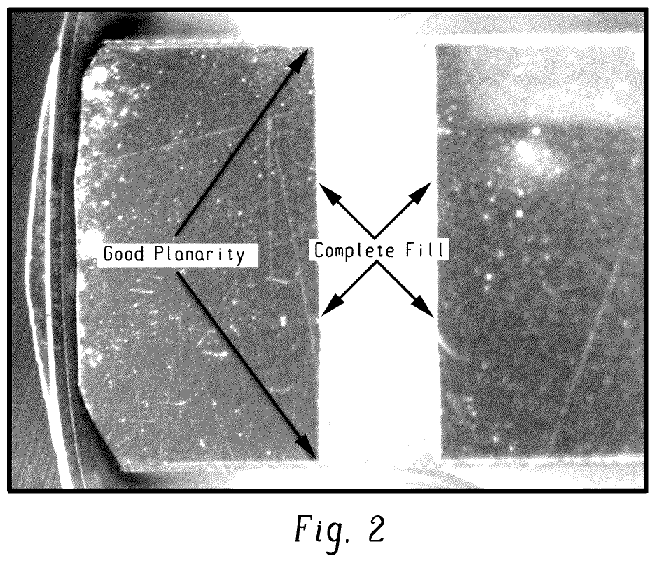

Sixty through-holes each having a diameter of 0.065 inches (1.651 mm) were drilled into an aluminum plate having a thickness 0.2 inches (5.08 mm). A ceramic filled PTFE composite material was blended with a lubricant (e.g., dipropylene glycol). The blend was extruded through a conical spaghetti die to form a composite rod. The resulting composite rod was washed, dried, and sintered at 371° C. to increase the density thereof. The length of the composite rod was selected to be 0.005 inches (0.127 mm) longer than the thickness of the aluminum plate. The composite rod diameter was 0.065″ (1.651 mm) after sintering. The extruded and cut ceramic filled PTFE rods were inserted into the through-holes drilled into the aluminum plate. The composite rods were compressed with a roller, resulting in “nail heads” on both sides of the plate. A silica filled PTFE dielectric layer obtained as Xtreme RO1200 Bondply from Rogers Corporation having a thickness of 0.003 inches (0.0762 mm) and a sheet of copper foil were laminated onto each side of the aluminum plate at a temperature of 371° C. and 1,000 pounds per square inch (psi) (6.89 megapascals (MPa)). Cross-sectioning and analysis revealed the ceramic filled PTFE rods completely filled and were bonded to holes in the aluminum plate (FIG. 2).

### Example 1

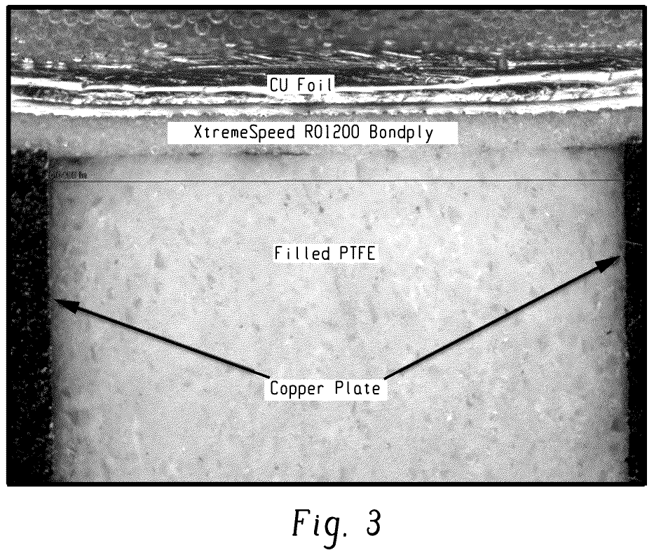

Through-holes each having a diameter of 0.040 inches (in) (1.016 mm) were drilled into a copper plate having a thickness of 0.110 inches (2.794 mm). PTFE was blended with fused amorphous silica at varying silica loadings. The blend was extruded through a conical spaghetti die to form a composite rod. The resulting composite rod was washed, dried and sintered at 371° C. to increase the density thereof. The length of the composite rod was selected to be 0.005 inches (0.127 mm) longer than the thickness of the copper plate. The composite rod diameter was 0.040 inches (1.016 mm) after sintering. The composite rods were manually inserted into the through-holes drilled into the copper plate. The composite rods were compressed with a roller, resulting in “nail heads” on both sides of the plate. A silica filled PTFE dielectric layer obtained as Xtreme Speed RO1200 bondply from Rogers Corporation having a thickness of 0.003 inches (0.0762 mm) was laminated onto each side of the copper plate at a temperature of 371° C. and 1,000 pounds per square inch (psi) (6.89 megapascals (MPa)). Cross-sectioning and analysis revealed the ceramic filled PTFE rods completely filled and were bonded to holes in the copper plate (FIG. 3).

### Example 2

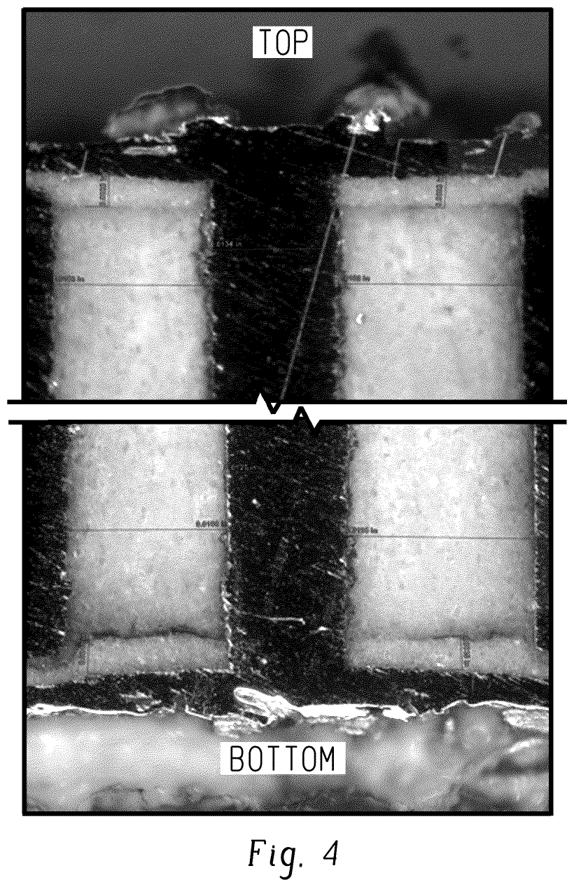

The process of Example 1 was repeated using a 0.2 inch (5.08 mm) thick aluminum plate having through-holes of a 0.065 inch (1.651 mm) diameter. Cross sectioning and analysis revealed the through-holes to be completely filled, no voiding, and no pulling away from the through-hole walls. Center through-holes having a diameter of 0.012 inches (0.3048 mm) were drilled into the filled through-holes of the metal plate, and the through-holes were plated by a conventional PTH process. Cross-sectioning and analysis revealed no voiding and reliable connections (FIG. 4).

This disclosure further encompasses the following aspects.

Aspect 1: A method for forming a plated through-hole structure, the method comprising: filling a first through-hole in a substrate with a composition having a coefficient of thermal expansion of less than 50 ppm/° C., wherein the first through-hole has a first opening at a first side of the substrate, a second opening at a second, opposite side of the substrate, and an interior surface defining the first through-hole and extending from the first opening to the second opening, wherein the composition is disposed on the interior surface of the first through-hole from the first opening to the second opening; forming a second through-hole in the first through-hole comprising the composition, wherein the second through-hole has a diameter less than a diameter of the first through-hole, an opening at the first side of the substrate, an opening at the second, opposite side of the substrate, and an interior surface defining the second through-hole and extending from the opening at the first side of the substrate to the opening at the second side of the substrate; and plating the interior surface of the second through-hole to provide the plated through-hole structure.

Aspect 2: The method of aspect 1, further comprising forming the first through-hole by drilling the first through-hole in the substrate.

Aspect 3: The method of aspect 1 or 2, wherein the composition comprises: a thermoplastic polymer or thermosetting polymer matrix; and a filler.

Aspect 4: The method of any of aspects 1 to 3, further comprising, prior to forming the second through-hole, applying pressure to the composition in the first through-hole to provide a head comprising the composition at one or both of the first opening and the second opening.

Aspect 5: The method of any of aspects 1 to 4, further comprising laminating a dielectric material on each side of the substrate prior to forming the second through-hole.

Aspect 6: The method of aspect 5, wherein the dielectric material comprises: a thermoplastic polymer or thermosetting polymer matrix; and optionally, a filler.

Aspect 7: The method of aspect 5 or 6, wherein the dielectric material and the composition for filling the first through-hole are the same.

Aspect 8: The method of any of aspects 1 to 7, further comprising laminating a conductive layer on a first of the plated through-hole structure, on a second, opposite side of the plated through-hole structure, or both the first and the second side of the plated through-hole structure.

Aspect 9: The method of aspect 8, wherein the conductive layer comprises copper.

Aspect 10: The method of any of aspects 1 to 9, wherein the composition comprises a thermoplastic polymer.

Aspect 11: The method of any of aspects 1 to 10, wherein the composition comprises a fluoropolymer.

Aspect 12: The method of aspect 11, wherein the fluoropolymer comprises polytetrafluoroethylene.

Aspect 13: The method of any of aspects 1 to 12, wherein the composition comprises a filler, preferably silica, titania, barium nanotitanate, or a combination thereof.

Aspect 14: The method of any of aspects 1 to 13, wherein the composition comprises a filler in an amount of 50 to 65 volume percent, based on the total volume of the composition.

Aspect 15: The method of any of aspects 1 to 14, wherein the composition is in the form of a cylindrical rod.

Aspect 16: The method of any of aspects 1 to 15, wherein the composition is in the form of a cylindrical rod having a diameter that is within 10% of a diameter of the first through-hole, preferably within 5% of the diameter of the first through-hole.

Aspect 17: The method of any of aspects 1 to 16, wherein the composition is in the form of a cylindrical rod having a diameter that is up to 10% greater than a diameter of the first through-hole, preferably up to 5% greater than the diameter of the first through-hole.

Aspect 18: The method of any of aspects 15 to 17, wherein the cylindrical rod has a length that is greater than a thickness of the substrate, preferably wherein the length of the cylindrical rod is at least 10% longer than the thickness of the substrate.

Aspect 19: The method of any of aspects 1 to 18, wherein the substrate is a conductive substrate, preferably comprising copper or aluminum.

Aspect 20: The method of any of aspects 1 to 19, wherein no voids are present between the interior surface of the first through-hole and the composition.

Aspect 21: A plated through-hole structure made by the method of any of aspects 1 to 20.

Aspect 22: A plated through-hole structure comprising: a substrate comprising a first through-hole having a first opening at a first side of the substrate, a second opening at a second, opposite side of the substrate, and an interior surface defining the first through-hole and extending from the first opening to the second opening; wherein the first through-hole has a composition having a coefficient of thermal expansion of less than 50 ppm/° C. disposed on the interior surface of the first through-hole from the first opening to the second opening; and a plated metal layer on the composition.

Aspect 23: The plated through-hole structure of aspect 22, wherein the substrate is a conductive substrate, preferably comprising copper or aluminum.

Aspect 24: The plated through-hole structure of aspect 22 or 23, wherein the composition comprises a thermoplastic polymer or thermosetting polymer matrix, preferably comprising a polytetrafluoroethylene; and a filler, preferably silica.

Aspect 25: The plated through-hole structure of any of aspects 21 to 24, wherein no voids are present between the interior surface of the first through-hole and the composition.

Aspect 26: A multilayer circuit board comprising the plated through-hole structure of any of aspects 21 to 25.

The compositions, methods, and articles can alternatively comprise, consist of, or consist essentially of, any appropriate materials, steps, or components herein disclosed. The compositions, methods, and articles can additionally, or alternatively, be formulated so as to be devoid, or substantially free, of any materials (or species), steps, or components, that are otherwise not necessary to the achievement of the function or objectives of the compositions, methods, and articles.

All ranges disclosed herein are inclusive of the endpoints, and the endpoints are independently combinable with each other. “Combinations” is inclusive of blends, mixtures, alloys, reaction products, and the like. The terms “first,” “second,” and the like, do not denote any order, quantity, or importance, but rather are used to distinguish one element from another. The terms “a” and “an” and “the” do not denote a limitation of quantity, and are to be construed to cover both the singular and the plural, unless otherwise indicated herein or clearly contradicted by context. “Or” means “and/or” unless clearly stated otherwise. Reference throughout the specification to “an aspect” means that a particular element described in connection with the aspect is included in at least one aspect described herein, and may or may not be present in other aspects. The term “combination thereof” as used herein includes one or more of the listed elements, and is open, allowing the presence of one or more like elements not named. In addition, it is to be understood that the described elements may be combined in any suitable manner in the various aspects.

Unless specified to the contrary herein, all test standards are the most recent standard in effect as of the filing date of this application, or, if priority is claimed, the filing date of the earliest priority application in which the test standard appears.

Unless defined otherwise, technical and scientific terms used herein have the same meaning as is commonly understood by one of skill in the art to which this application belongs. All cited patents, patent applications, and other references are incorporated herein by reference in their entirety. However, if a term in the present application contradicts or conflicts with a term in the incorporated reference, the term from the present application takes precedence over the conflicting term from the incorporated reference.

Compounds are described using standard nomenclature. For example, any position not substituted by any indicated group is understood to have its valency filled by a bond as indicated, or a hydrogen atom. A dash (“—”) that is not between two letters or symbols is used to indicate a point of attachment for a substituent. For example, —CHO is attached through carbon of the carbonyl group.

While particular embodiments have been described, alternatives, modifications, variations, improvements, and substantial equivalents that are or may be presently unforeseen may arise to applicants or others skilled in the art. Accordingly, the appended claims as filed and as they may be amended are intended to embrace all such alternatives, modifications variations, improvements, and substantial equivalents.

1. A method for forming a plated through-hole structure, the method comprising:
filling a first through-hole in a substrate with a composition having a coefficient of thermal expansion of less than 50 ppm/° C., wherein
the first through-hole has
a first opening at a first side of the substrate,
a second opening at a second, opposite side of the substrate, and
an interior surface defining the first through-hole and extending from the first opening to the second opening,
wherein the composition is disposed on the interior surface of the first through-hole from the first opening to the second opening;
forming a second through-hole in the first through-hole comprising the composition, wherein the second through-hole has
a diameter less than a diameter of the first through-hole,
an opening at the first side of the substrate,
an opening at the second, opposite side of the substrate, and
an interior surface defining the second through-hole and extending from the opening at the first side of the substrate to the opening at the second side of the substrate; and
plating the interior surface of the second through-hole to provide the plated through-hole structure.

2. The method of claim 1, further comprising forming the first through-hole by drilling the first through-hole in the substrate.

3. The method of claim 1, wherein the composition comprises:
a thermoplastic polymer or thermosetting polymer matrix; and
a filler.

4. The method of claim 1, further comprising, prior to forming the second through-hole, applying pressure to the composition in the first through-hole to provide a head comprising the composition at one or both of the first opening and the second opening.

5. The method of claim 1, further comprising laminating a dielectric material on each side of the substrate prior to forming the second through-hole.

6. The method of claim 5, wherein the dielectric material comprises:
a thermoplastic polymer or thermosetting polymer matrix; and
optionally, a filler.

7. The method of claim 5, wherein the dielectric material and the composition for filling the first through-hole are the same.

8. The method of claim 1, further comprising laminating a conductive layer on a first of the plated through-hole structure, on a second, opposite side of the plated through-hole structure, or both the first and the second side of the plated through-hole structure.

9. The method of claim 8, wherein the conductive layer comprises copper.

10. The method of claim 1, wherein the composition comprises a thermoplastic polymer.

11. The method of claim 1, wherein the composition comprises a fluoropolymer.

12. The method of claim 11, wherein the fluoropolymer comprises polytetrafluoroethylene.

13. The method of claim 1, wherein the composition comprises a filler, preferably silica, titania, barium nanotitanate, or a combination thereof.

14. The method of claim 1, wherein the composition comprises a filler in an amount of 50 to 65 volume percent, based on the total volume of the composition.

15. The method of claim 1, wherein the composition is in the form of a cylindrical rod.

16. The method of claim 1, wherein the composition is in the form of a cylindrical rod having a diameter that is within 10% of a diameter of the first through-hole, preferably within 5% of the diameter of the first through-hole.

17. The method of claim 1, wherein the composition is in the form of a cylindrical rod having a diameter that is up to 10% greater than a diameter of the first through-hole, preferably up to 5% greater than the diameter of the first through-hole.

18. The method of claim 15, wherein the cylindrical rod has a length that is greater than a thickness of the substrate, preferably wherein the length of the cylindrical rod is at least 10% longer than the thickness of the substrate.

19. The method of claim 1, wherein the substrate is a conductive substrate, preferably comprising copper or aluminum.

20. The method of claim 1, wherein no voids are present between the interior surface of the first through-hole and the composition.

21. A plated through-hole structure made by the method of claim 1.

22. A plated through-hole structure comprising:
a substrate comprising a first through-hole having
a first opening at a first side of the substrate,
a second opening at a second, opposite side of the substrate, and
an interior surface defining the first through-hole and extending from the first opening to the second opening;
wherein the first through-hole has
a composition having a coefficient of thermal expansion of less than 50 ppm/° C. disposed on the interior surface of the first through-hole from the first opening to the second opening; and
a plated metal layer on the composition.

23. The plated through-hole structure of claim 22, wherein the substrate is a conductive substrate, preferably comprising copper or aluminum.

24. The plated through-hole structure of claim 22, wherein the composition comprises
a thermoplastic polymer or thermosetting polymer matrix, preferably comprising a polytetrafluoroethylene; and
a filler, preferably silica.

25. The plated through-hole structure of claim 22, wherein no voids are present between the interior surface of the first through-hole and the composition.

26. A multilayer circuit board comprising the plated through-hole structure of claim 22.
